(19) United States
(12) Patent Application Publication
(10) Pub. No.: US 2026/0371668 A1
(43) Pub. Date: Nov. 19, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Yan-Ting Lin, Baoshan Township (TW); Chien-I Kuo, Zhubei City (TW); Ming-Hua Yu, Hsinchu (TW); Chii-Horng Li, Zhubei City (TW)

(21) Appl. No.: 19/751,794

(22) Filed: Jul. 23, 2026

Related U.S. Application Data
(63) Continuation of application No. 18/955,099, filed on Nov. 21, 2024.
(60) Provisional application No. 63/667,178, filed on Jul. 3, 2024.

(51) Int. Cl. H10D 62/10; H10D 30/01; H10D 30/43; H10D 30/67; H10D 64/01; H10D 84/85; H10P 14/692; H10P 50/28

(52) U.S. Cl. CPC H10D 62/121; H10D 30/014; H10D 30/43; H10D 30/6713; H10D 30/6735; H10D 30/6757; H10D 64/017; H10D 84/85; H10P 14/69391; H10P 50/283

(57) ABSTRACT

In an embodiment, a method may include forming a multi-layer stack over a substrate, the multi-layer stack having alternating layers of first semiconductor layers and second semiconductor layers. The method may also include forming first source/drain regions adjacent the first semiconductor layers and the second semiconductor layers in a first region, the first source/drain regions having a cap layer, forming a protection layer over the first source/drain regions, forming second source/drain regions adjacent the first semiconductor layers and the second semiconductor layers in a second region, removing the protection layer from over the first source/drain regions, replacing the first semiconductor layers in the first region with a first metal gate structure, and replacing the first semiconductor layers in the second region with a second metal gate structure.

### PRIORITY CLAIM AND CROSS-REFERENCE

This application is a continuation of U.S. Patent Application No. 18/955,099, filed Nov. 21, 2024, which claims the benefit of U.S. Provisional Application No. 63/667,178, filed on Jul. 3, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 11A, 11B, 11C, 12A, 12B, 13A, 13B, 14A, 14B, 15A, 15B, 16A, 16B, 16C, 17A, 17B, 17C, 18A, 18B, 19A, 19B, 20A, 20B, 21A, 21B, 22A, 22B, 22C, 23A, 23B, 23C, 24A, 24B,24C, are cross-sectional views of intermediate stages in the manufacturing of nano-FETs, in accordance with some embodiments.

FIGS. 25 and 26 are cross-sectional views of a nano-FET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to semiconductor devices and methods for enhancing performance and reducing defects, particularly in the context of nanostructure field-effect transistors (nano-FETs). The present disclosure addresses the challenges associated with protecting source/drain regions during the manufacturing process. As semiconductor technology advances towards smaller and smaller nodes, the need for more precise and reliable fabrication techniques becomes increasingly important. This disclosure introduces a silicon-based cap layer designed to enhance the protection of p-type source/drain regions in nano-FETs.

In some configurations of nano-FET fabrication, the sequence of source/drain epitaxial processes involves forming n-type epitaxial regions after P-type epitaxial regions. The P-type epitaxial regions are protected by a protection layer (may be an aluminum oxide layer) during the N-type epitaxial process. However, the protection layer may not always provide uniform or sufficient coverage. Consequently, the underlying epitaxial layers of the p-type epitaxial structure can be susceptible to damage from etching chemicals, particularly chlorine-containing etchants used in subsequent N-type source/drain formation steps.

This disclosure addresses this issue by introducing a silicon cap layer as a part of the p-type source/drain epitaxial structure. The cap layer may be high boron-doped silicon layer. This cap layer, with a controlled thickness of 2-6 nanometers, fully covers the underlying layer(s) and serves as a protective barrier. The cap layer is particularly effective in safeguarding against HCl and Cl₂ etchants, providing a layer of protection when the protection layer proves insufficient.

The advantages of this approach are numerous. First, it significantly enhances the protection of p-type source/drain regions, ensuring their integrity throughout the fabrication process. This improved protection translates to increased reliability and potentially higher performance of the resulting nano-FETs. The versatility of the cap layer, which can be composed of various materials such as Si, SiB, SiGe, or SiGeB, allows for flexibility in manufacturing processes and enables optimization of transistor characteristics.

Furthermore, the precise control over the thickness and shape of the cap layer enables fine-tuning of its protective properties, allowing manufacturers to tailor the fabrication process to specific requirements. The approach integrates with existing nano-FET fabrication workflows, minimizing the need for extensive modifications to established manufacturing processes. By providing enhanced etch resistance and preserving the integrity of P-type source/drain regions, this approach enables the production of more reliable and higher-performing nano-FETs, which are components in a wide range of electronic devices, from smartphones and computers to advanced AI systems and IoT devices.

Embodiments are described below in a particular context, nano-FET transistors. Various embodiments may be applied, however, to dies comprising other types of transistors (e.g., fin field effect transistors (FinFETs), planar transistors, or the like) in combination with the nano-FETs.

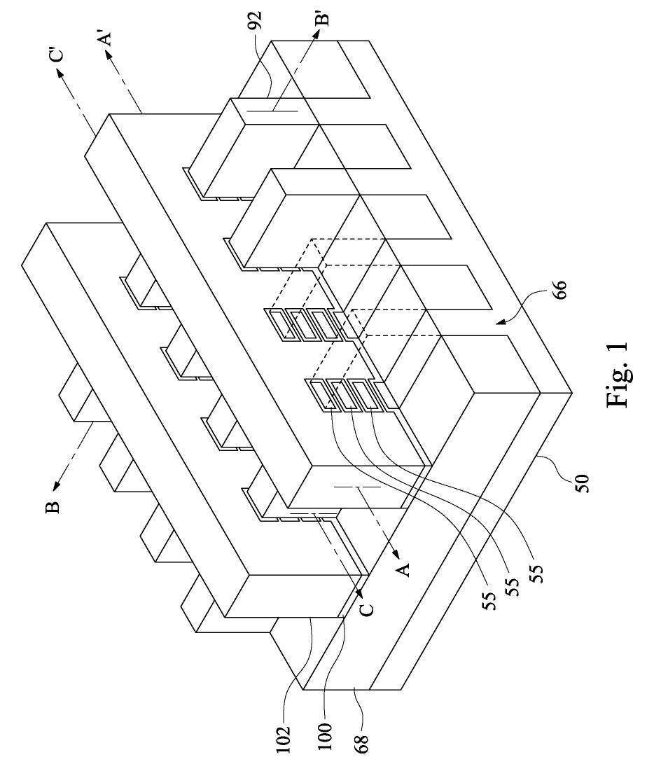

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

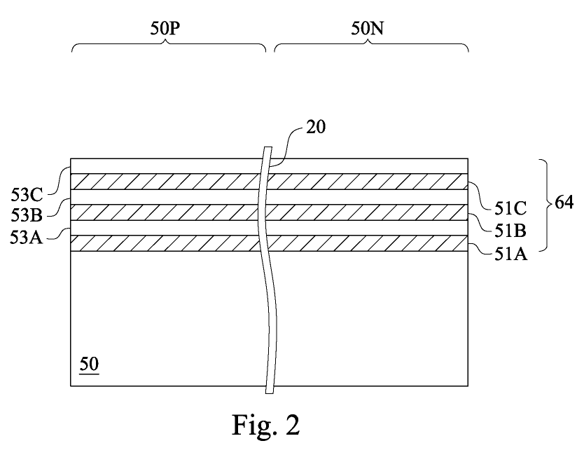

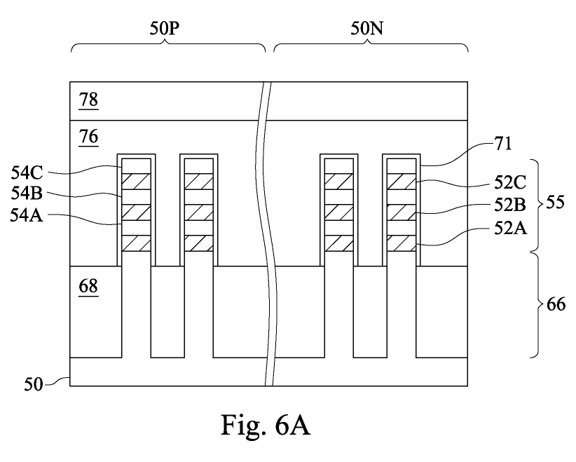

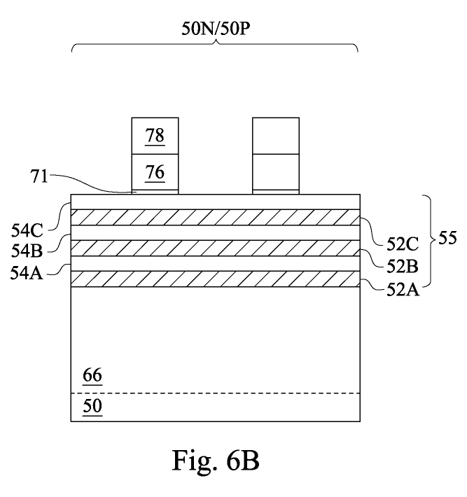

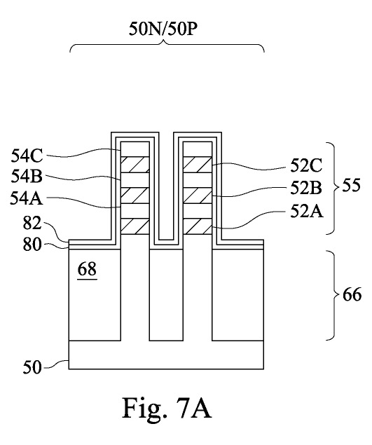

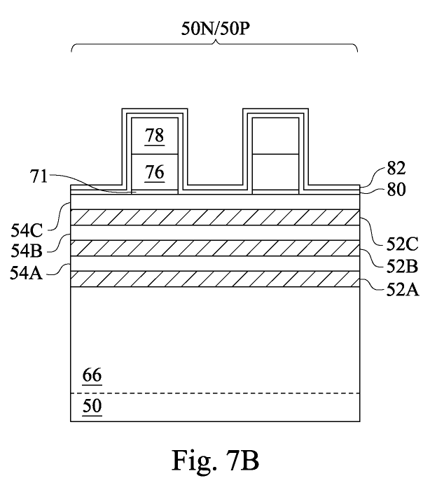

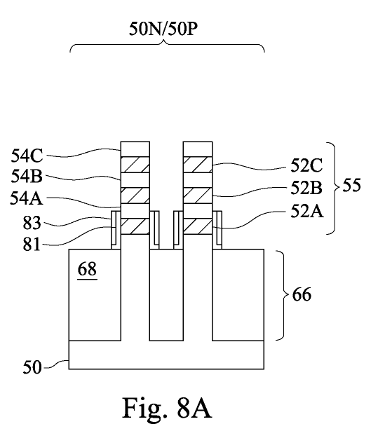

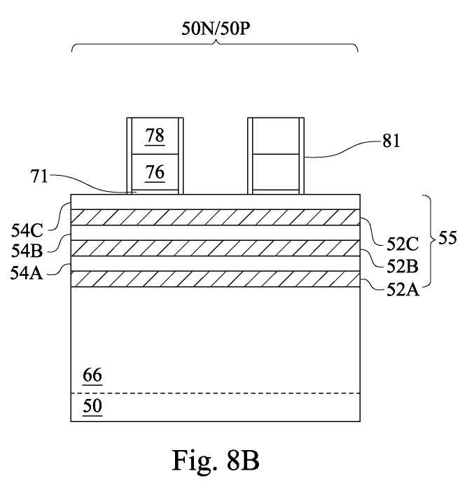

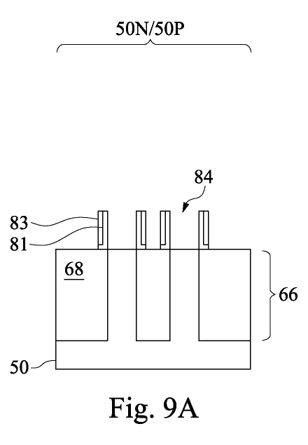

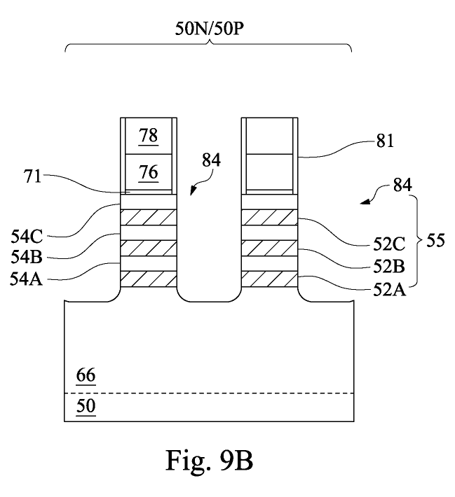

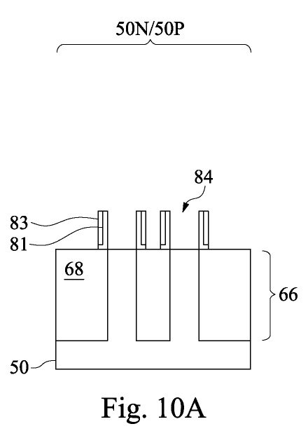

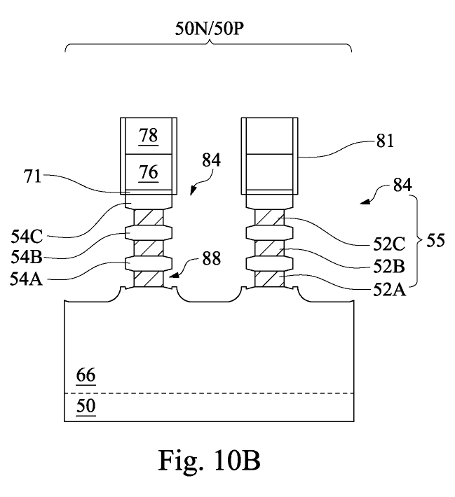

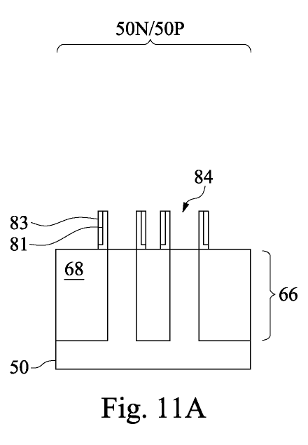

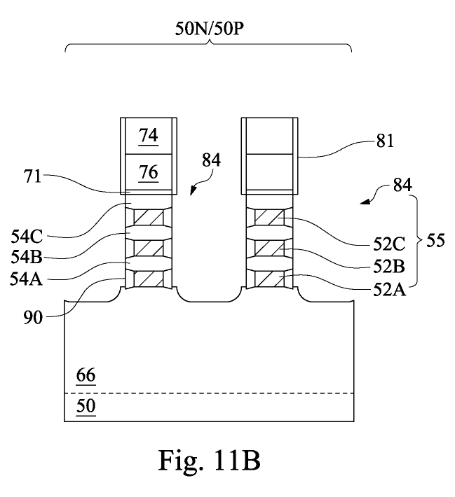

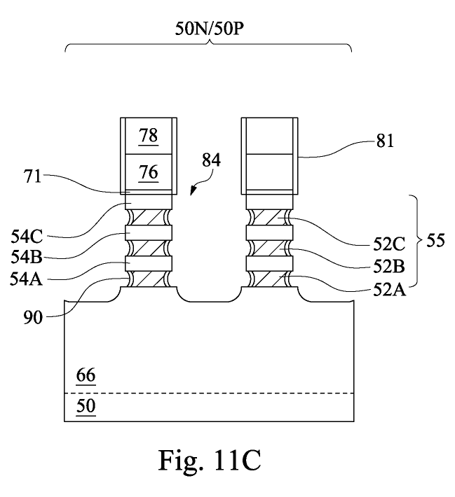

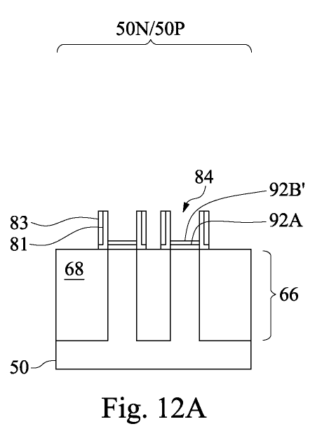

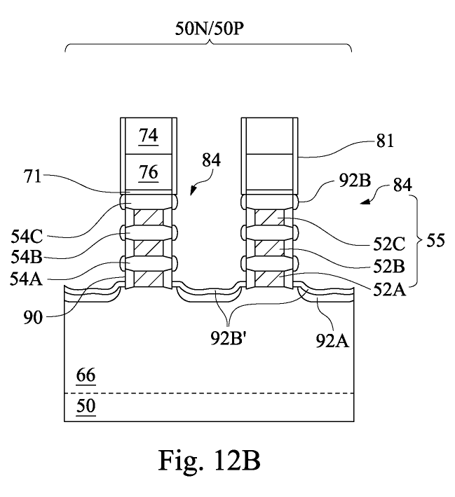

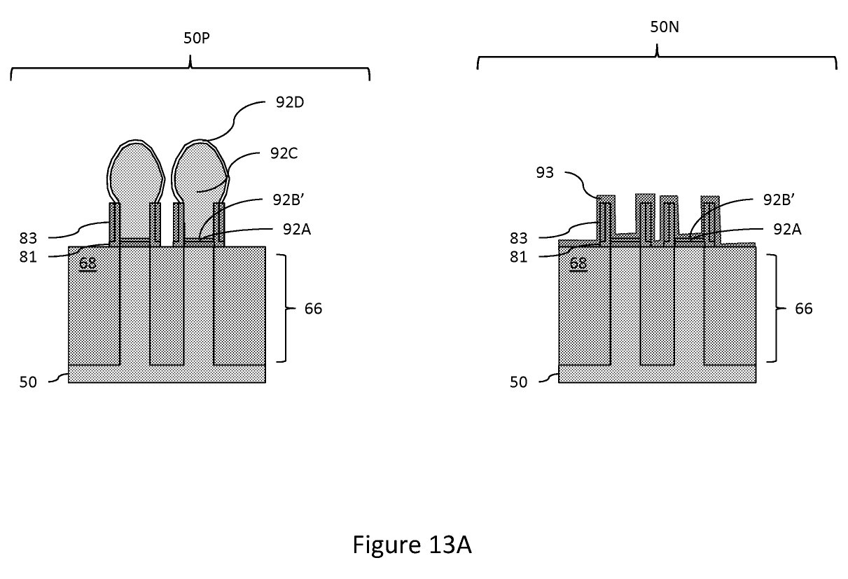

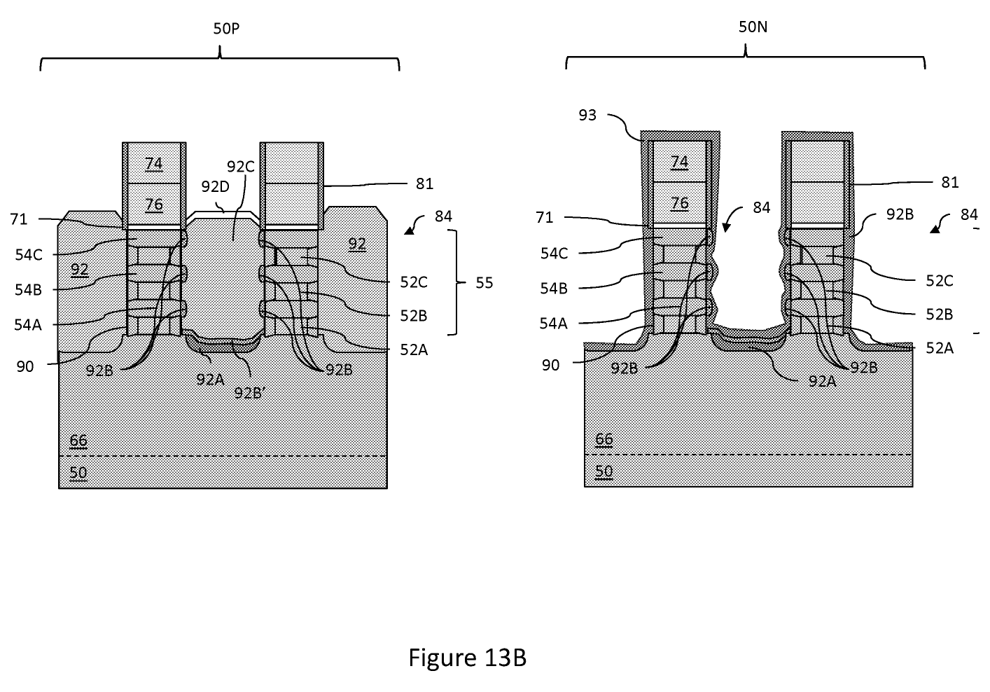

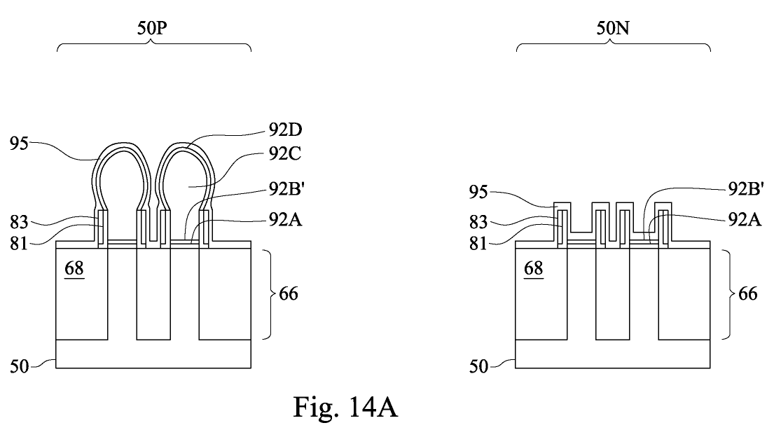

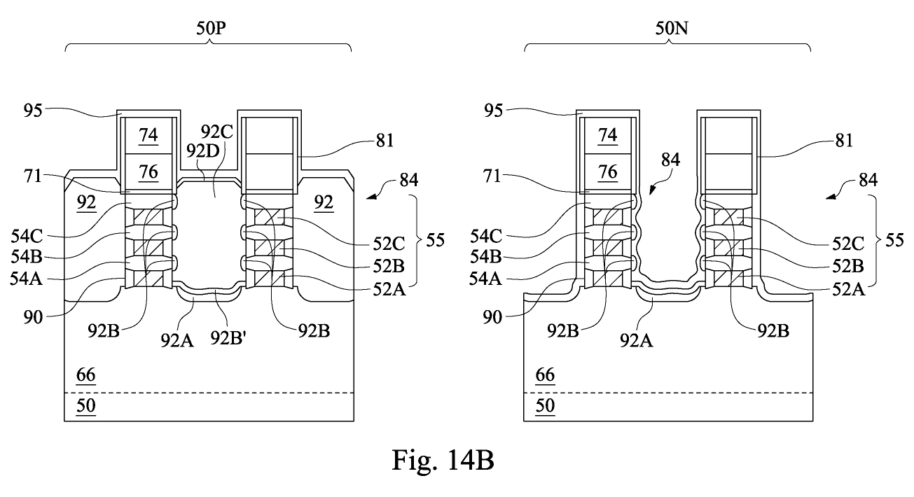

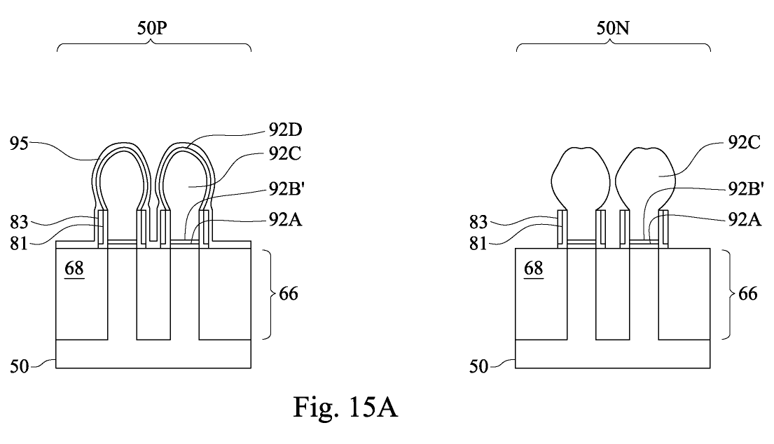

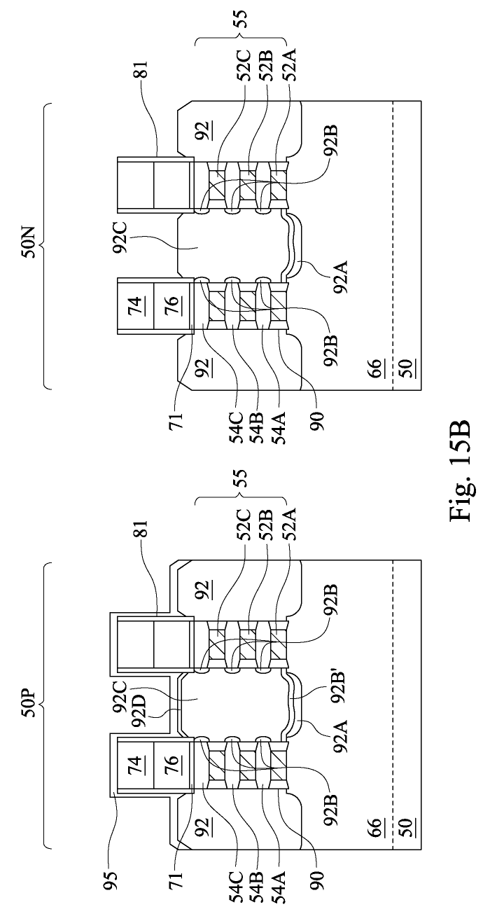

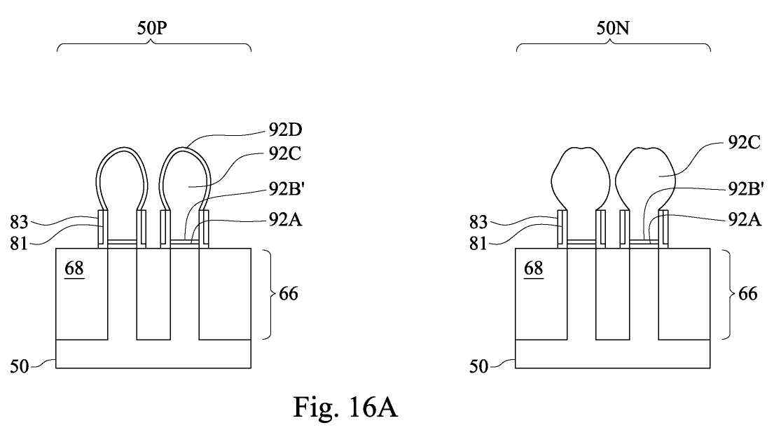

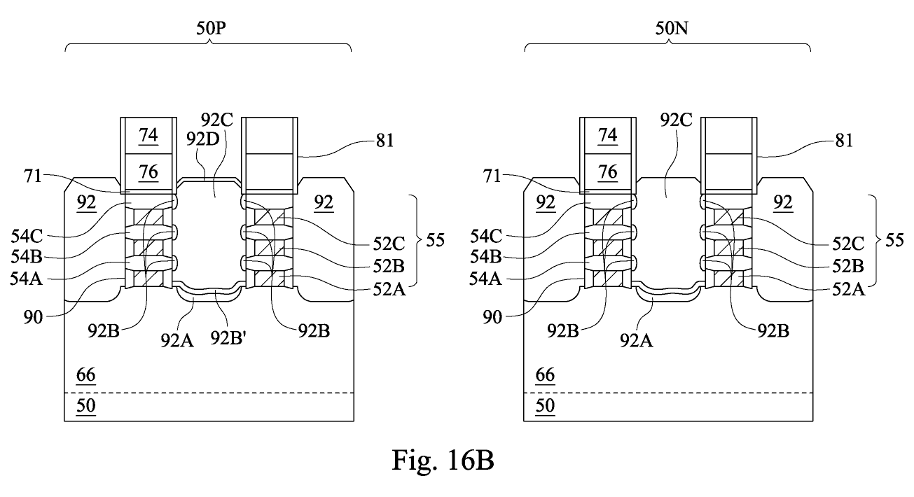

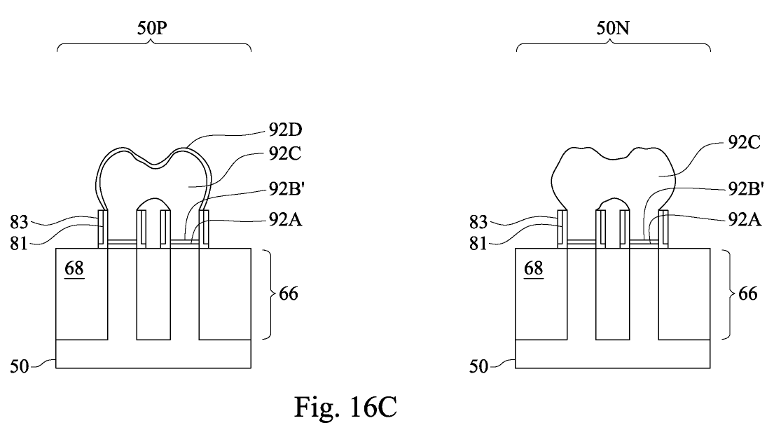

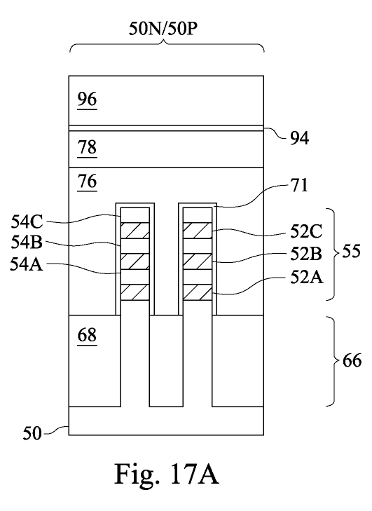

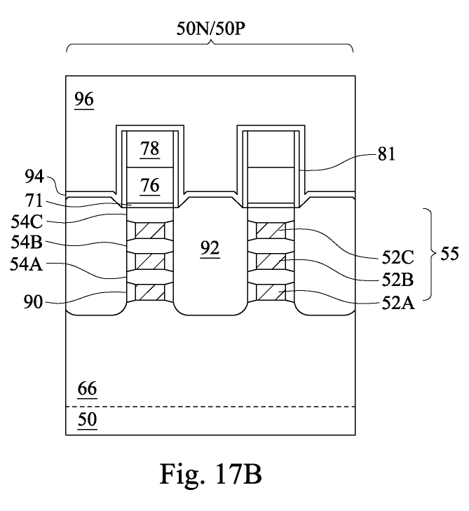

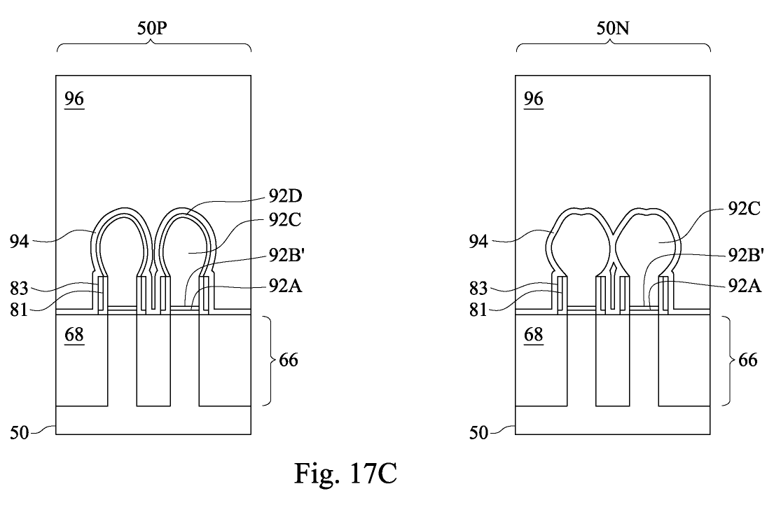

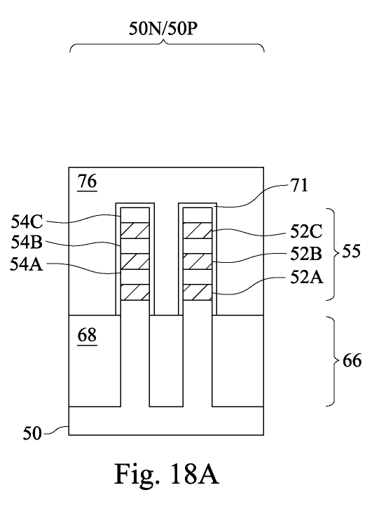

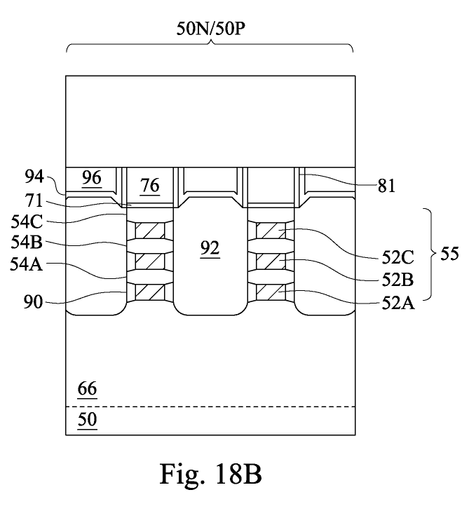

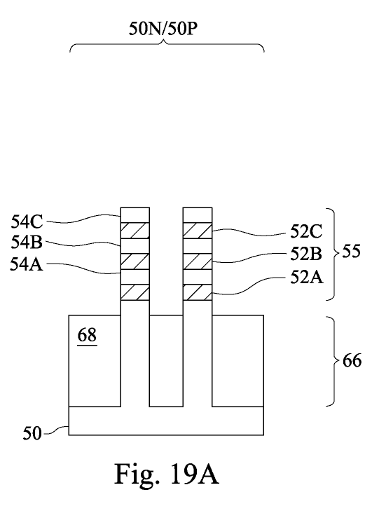

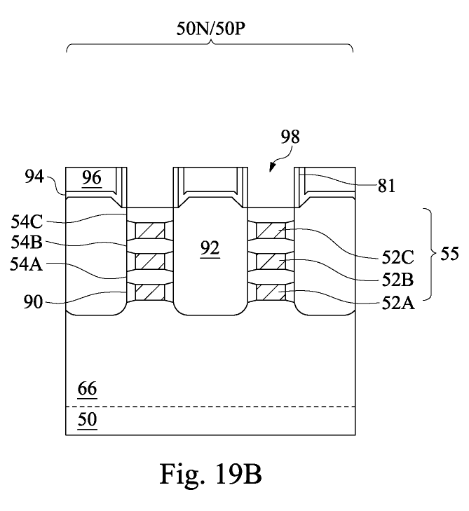

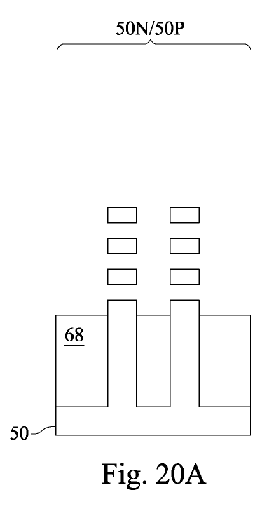

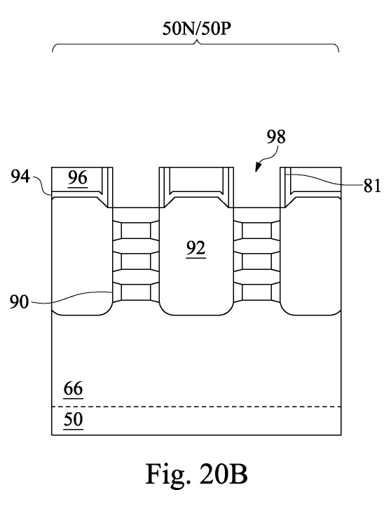

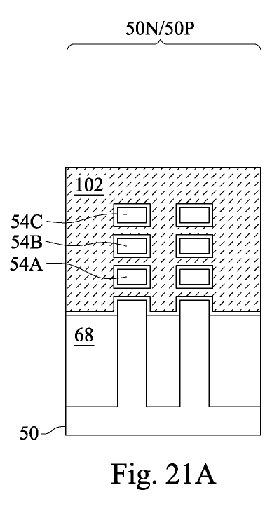

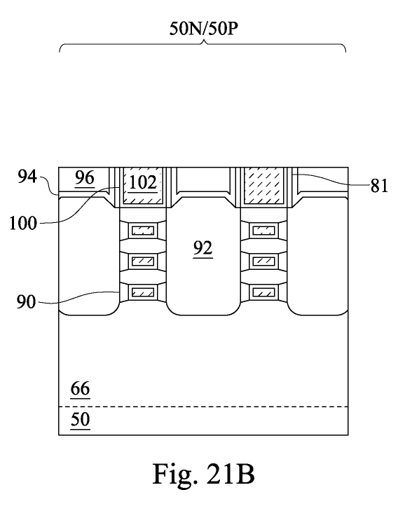

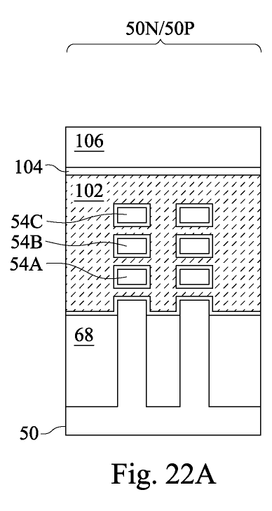

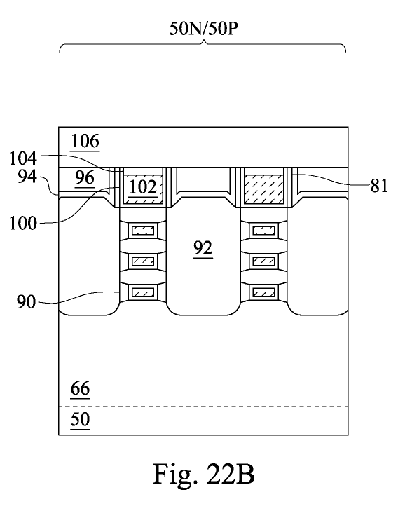

FIGS. 2-24C are cross-sectional views of intermediate stages in the manufacturing of nano-FETs used in the SRAM device of FIG. 1B, in accordance with some embodiments. FIGS. 2 through 5, 6A, 17A, 18A, 19A, 20A, 21A, 22A, 23A,and 24A, illustrate reference cross-section A-A’ illustrated in FIG. 1. FIGS. 6B, 7B, 8B, 9B, 10B, 11B, 11C, 12B, 13B, 14B, 15B, 16B, 17B, 18B, 19B, 20B, 21B, 22B, 23B, and 24B, illustrate reference cross-section B-B’ illustrated in FIG. 1. FIGS. 7A, 8A, 9A, 10A, 11A, 12A, 13A, 14A, 15A, 16A, 16C, 17C, 22C, 23C,and 24C, illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

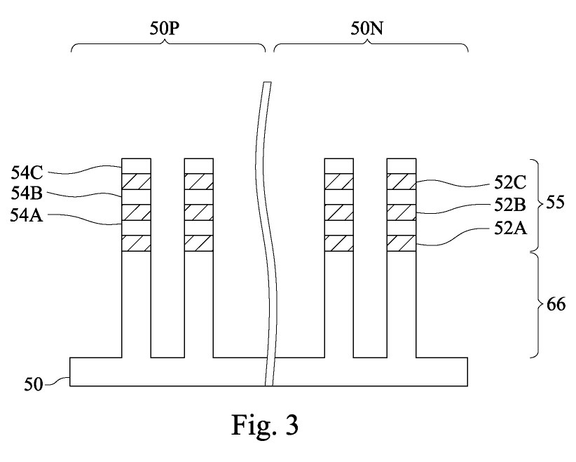

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

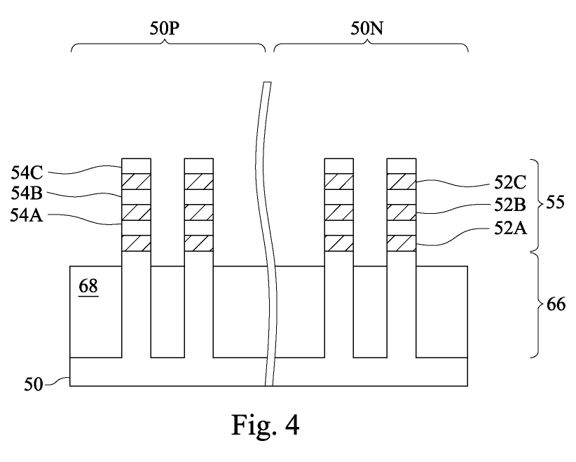

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, hydrogen fluoride, diluted hydrogen fluoride, another fluorine-based etchant, or the like may be used.

The process described above with respect to FIGS. 2-4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from 10¹³ atoms/cm³ to 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from 10¹³ atoms/cm³ to 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

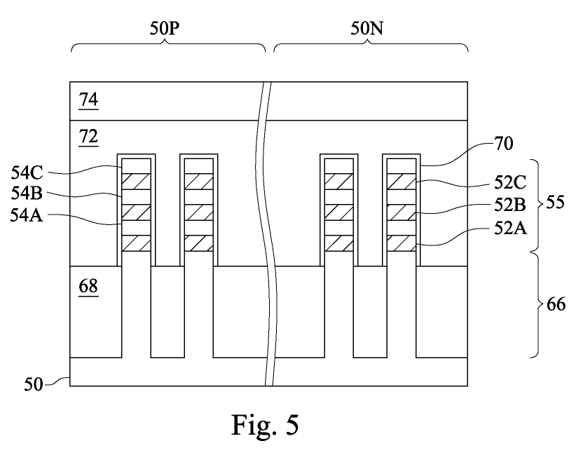

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A-24C illustrate various additional steps in the manufacturing of embodiment devices. FIGS. 6A, 6B, 7A, 7B, 8A, 8B, 9A, 9B, 10A, 10B, 11A, 11B, 11C, 12A, 12B, 17A, 17B, 18A, 18B, 19A, 19B, 20A, 20B, 21A, 21B, 22A, 22B, 23A, 23B, 24A and 24B, illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-align subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 84 are formed in the fins 66, the nanostructures 55, and the substrate 50 in both the p-type region 50P and the n-type region 50N. Epitaxial source/drain regions will be subsequently formed in the first recesses 84. The first recesses 84 may extend through the first nanostructures 52 and the second nanostructures 54, and into the substrate 50. As illustrated in FIG. 9A, top surfaces of the STI regions 58 may be level with bottom surfaces of the first recesses 84. In various embodiments, the fins 66 may be etched such that bottom surfaces of the first recesses 84 are disposed below the top surfaces of the STI regions 68; or the like. The first recesses 84 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 84. A single etch process or multiple etch processes may be used to etch each layer of the nanostructures 55 and/or the fins 66. Timed etch processes may be used to stop the etching of the first recesses 84 after the first recesses 84 reach a desired depth.

In FIGS. 10A and 10B, portions of sidewalls of the layers of the multi-layer stack 56 formed of the first semiconductor materials (e.g., the first nanostructures 52) exposed by the first recesses 84 are etched to form sidewall recesses 88 in both the p-type region 50P and the n-type region 50N. Although sidewalls of the first nanostructures 52 in sidewall recesses 88 are illustrated as being straight in FIG. 10B, the sidewalls may be concave or convex (see e.g., FIG. 11C). The etching may be isotropic or anisotropic.

As an example of the process, etchants selective to the first semiconductor materials are used to etch the first nanostructures 52 such that the second nanostructures 54 and the substrate 50 remain relatively unetched (although some etching may occur) as compared to the first nanostructures 52. In an embodiment in which the first nanostructures 52 include, e.g., SiGe, and the second nanostructures 54 include, e.g., Si or SiC, a wet or dry etch process with tetramethylammonium hydroxide (TMAH), ammonium hydroxide (NH₄OH), or the like may be used to etch sidewalls of the first nanostructures 52.

In some embodiments, because of the etch selectivity between the materials of the first nanostructures 52 and the second nanostructures 54, the recesses 88 may expand up and/or down, for a more trapezoidal shape for the recesses 88. In some embodiments, the recesses will have flat upper and bottom surfaces.

In FIGS. 11A-11C, first inner spacers 90 are formed in the sidewall recess 88 in both the p-type region 50P and the n-type region 50N. The first inner spacers 90 may be formed by depositing an inner spacer layer (not separately illustrated) over the structures illustrated in FIGS. 10A and 10B. The first inner spacers 90 act as isolation features between subsequently formed source/drain regions and a subsequently formed gate structure (discussed further below).

The inner spacer layer may be deposited by a conformal deposition process, such as CVD, ALD, or the like, thereby taking the shape of the recesses 88. The inner spacer layer may comprise a material such as silicon nitride or silicon oxynitride, although any suitable material, such as low-dielectric constant (low-k) materials having a k-value less than 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54. Once formed, the first inner spacers 90 have taken the shape of the sidewalls of the recesses 88, such that the first inner spacers 90 may have flat upper/bottom surfaces or have expanding surfaces and have a trapezoidal shape.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54.

In FIGS. 12A-16C, epitaxial source/drain regions 92 are formed in the first recesses 84 in both the p-type region 50P and the n-type region 50N. The source/drain regions 92 may exert stress on the second nanostructures 54 in the n-type region 50N and/or on the first nanostructures 52 in the p-type region 50P, thereby improving performance. In some embodiments, the epitaxial source/drain regions 92 may comprise one or more semiconductor material layers, and in some embodiments, the epitaxial source/drain regions 92 may be formed in the p-type region 50P before being formed in the n-type region 50N.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 84 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 84 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

FIGS. 12A-16C illustrate an exemplary process for forming the epitaxial source/drain regions 92 in the p-type region 50P before being formed in the n-type region 50N. In FIGS. 12A-B , a first semiconductor material layer 92A and a second semiconductor material layer 92B are formed in in the first recesses 84 in both the p-type region 50P and the n-type region 50N. As described in subsequent figures, the epitaxial source/drain regions may further include a third semiconductor material layer 92C, and a fourth semiconductor material layer 92D. Although four layers are illustrated and described, any number of semiconductor material layers may be used for the epitaxial source/drain regions 92. In some embodiments, the second semiconductor material layer 92B is omitted.

The first semiconductor material layer 92A (also referred to as L0) may be an undoped or lightly doped layer that prevents or reduces diffusion of dopants from the overlying epitaxial layers (e.g., particularly the third and fourth semiconductor material layers 92C and 92D) into the underlying substrate 50. In a specific example, the first semiconductor material layer 92A may be a silicon layer that is substantially free of germanium. In some embodiments, the first semiconductor material layer 92A may be formed by a bottom-up epitaxial growth process.

In embodiments that include the second semiconductor material layer 92B (also referred to as L1), the second semiconductor material layer 92B may also be a silicon layer that is substantially free of germanium. In some embodiments, second semiconductor material layer 92B may be retard the etchant leakage from the first nanostructures 52A-C when the first nanostructures 52A-C are removed (see, e.g., FIGS. 20A-B ). In some embodiments, the second semiconductor material layer 92B may comprise silicon, silicon doped by boron (SiB), the like, or a combination thereof. The second semiconductor material layer 92B may be formed by an epitaxial process including silane (SiH₄) dichlorosilane (DCS) for the silicon precursor, and may include B₂H₆ or BCl₃ for the boron precursor. The second semiconductor material layer 92B may include lateral portions 92B' that results from applying the doping process to the undoped or lightly doped first semiconductor material layer 92A. In subsequent figures along the cross-section of FIG. 12B, the multiple layers 92A-92D of the epitaxial source/drain regions 92 are only illustrated in the middle recesses 84, but the outer recesses 84 of the respective regions have similar configurations of the epitaxial source/drain regions 92.

In FIGS. 13A-B the remaining layers of the epitaxial source/drain regions 92 are formed in the p-type region 50P. This process may begin by forming a mask layer 93 (may also be referred to as a protection layer 93) over the n-type region 50N and the p-type region 50P. In some embodiments, the mask layer 93 comprises an oxide layer, such as aluminum oxide, but other suitable materials are within the scope of the disclosure. The mask layer 93 may be a conformal layer having a substantially uniform thickness (within process variations) on vertical and horizontal surfaces. The mask layer 93 may be removed from the p-type region 50P. In some embodiments, the removal of the mask layer 93 is performed by forming a photoresist and/or mask (not separately illustrated) and patterning the photoresist and/or mask to expose the p-type region 50P following by an etching process to remove the exposed mask layer 93 in the p-type region 50p. Once the mask layer 93 is patterned, the third semiconductor material layer 92C (may be referred to as L2) may be formed over the second semiconductor material layer 92B, and the fourth semiconductor material layer 92D (may be referred to as L3) may be formed over the third semiconductor material layer 92C.

The epitaxial growth process of the source/drain regions 92 in the p-type region 50P involves the sequential formation of layers third semiconductor material layer 92C and the fourth semiconductor material layer 92D. The third semiconductor material layer 92C is epitaxially grown from the underlying layer (first or second semiconductor material layer 92A or 92B and/or second semiconductor nanostructures 54 depending on the presence of the second semiconductor material layer 92B). The third semiconductor material layer 92C may be a silicon germanium layer doped with boron. In some embodiments, the boron concentration of the third semiconductor material layer 92C ranges from 7x10²⁰ atoms/cm³ to 1x10²¹ atoms/cm³, and the germanium concentration is within the range of 50% to 60%.

Following the formation of the third semiconductor material layer 92C, the fourth semiconductor material layer 92D (may also be referred to as a cap layer 92D) is epitaxially grown from the third semiconductor material layer 92C. The fourth semiconductor material layer 92D may serve as a protective layer and can have various compositions. In one configuration, the fourth semiconductor material layer 92D is a silicon germanium layer doped with boron. In some embodiments, the fourth semiconductor material layer 92D can have a boron concentration in a range from 0 to 1x10²² atoms/cm³, and the germanium concentration is less than 20%. In some embodiments, the fourth semiconductor material layer 92D may be composed of silicon without germanium, or it may be a pure silicon layer without boron. In some embodiments, the fourth semiconductor material layer 92D may be made of Si, SiB, SiGe, or SiGeB. Regardless of its specific composition, the germanium concentration in the third semiconductor material layer 92C is greater than that in the fourth semiconductor material layer 92D.

When the fourth semiconductor material layer 92D is a highly boron-doped silicon layer, it provides protection against post p-type epitaxy wet clean processes or HCl etching during the n-type epitaxy process. This protective function is particularly useful when the subsequently formed protection layer 95 (see, e.g., FIGS. 14A-B ) does not completely cover the source/drain regions 92 in the p-type region 50P. The fourth semiconductor material layer 92D acts as a protective layer, shielding against etching damage during the formation of n-type epitaxial source/drain regions 92. Specifically, in some embodiments, the fourth semiconductor material layer 92D offers protection against HCl and Cl₂ etchants, as well as other chlorine-containing etchants.

The fourth semiconductor material layer 92D layer is designed to fully cover the third semiconductor material layer 92C layer. In some embodiments, the fourth semiconductor material layer 92D has a thickness in a range from 2 nm to 6 nm, and the fourth semiconductor material layer 92D maintains this thickness along the (001), (110), and (111) crystallographic directions. This uniform coverage ensures comprehensive protection for the underlying layers during subsequent processing steps.

In some embodiments, each of the first semiconductor material layer 92A, the second semiconductor material layer 92B, the third semiconductor material layer 92C, and the fourth semiconductor material layer 92D may be formed of different semiconductor materials and may be doped to different dopant concentrations.

In FIGS. 14A-B , the mask layer 93 is removed from the n-type region 50N and a protection layer 95 is formed in both regions 50P and 50N. In some embodiments, the protection layer 95 comprises an oxide layer, such as aluminum oxide, but other suitable materials are within the scope of the disclosure. The protection layer 95 may be a conformal layer having a substantially uniform thickness (within process variations) on vertical and horizontal surfaces.

In FIGS. 15A-B , the protection layer 95 is removed from the n-type region 50N and the remaining portions of the epitaxial source/drains 92 are formed in the n-type region 50N. In some embodiments, the removal of the protection layer 95 is performed by forming a mask (not separately illustrated) and patterning the mask to expose the n-type region 50N following by an etching process to remove the exposed protection layer 95 in the n-type region 50N.

The formation of the epitaxial source/drain regions 92 in the n-type region 50N may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. In some embodiments, the third semiconductor material layer 92C is grown in n-type region 50N with suitable material compositions. The cap layer 92D may be omitted from the n-type region 50N. The formation of the third semiconductor material layer 92C in the n-type region 50N may include etching steps using chlorine-containing etchants, such as in deposition and etch cycles. As discussed above, the fourth semiconductor material layer 92D in the p-type region 50P acts as a protective layer, shielding against etching damage during the formation of n-type epitaxial source/drain regions 92. Specifically, in some embodiments, the fourth semiconductor material layer 92D offers protection against HCl and Cl2 etchants, as well as other chlorine-containing etchants.

As illustrated in FIG. 15B, the epitaxial source/drain regions 92 in both regions 50P and 50N are formed in the first recesses 84 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

During their respective formation processes in each of the regions 50N and 50P, the epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. In some embodiments, the epitaxial source/drain regions 92 may be in situ doped during growth.

By utilizing the fourth semiconductor material layer 92D (may be referred to as a cap layer or L3 layer) in the source/drain regions 92 of the p-type region 50P, several advantages are achieved. First, this approach significantly enhances the protection of p-type source/drain regions, ensuring their integrity throughout the fabrication process. This improved protection translates to increased reliability and higher performance of the resulting nano-FETs. The versatility of the fourth semiconductor material layer 92D layer, which can be composed of various materials such as Si, SiB, SiGe, or SiGeB, allows for flexibility in manufacturing processes and enables optimization of transistor characteristics. Further, the precise control over the thickness and shape of the fourth semiconductor material layer 92D enables fine-tuning of its protective properties. The disclosed process also integrates with existing nano-FET fabrication workflows, minimizing the need for extensive modifications to established manufacturing processes.

In FIGS. 16A-16C, the protection layer 95 is removed after the completion of the formation of the epitaxial source/drain regions 92. As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 16C. In other embodiments, adjacent epitaxial source/drain regions 92 remain separated after the epitaxy process is completed as illustrated by FIG. 16A. In the embodiments illustrated in FIGS. 16A and 16C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

In FIGS. 17A-17C, a first interlayer dielectric (ILD) 96 is deposited over the structure illustrated in FIGS. 6A, 16B, and 16A, (the processes of FIGS. 7A-16C do not alter the cross-section illustrated in FIGS. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 18A-18B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 19A and 19B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 20A and 20B, the first nanostructures 52 in the n-type region 50N and the p-type region 50P are removed. The first nanostructures 52 may be removed by performing an isotropic etching process such as wet etching or the like using etchants which are selective to the materials of the first nanostructures 52, while the second nanostructures 54, the substrate 50, and the STI regions 58 remain relatively unetched as compared to the first nanostructures 52. In embodiments in which the first nanostructures 52 include, e.g., SiGe, and the second nanostructures 54 include, e.g., Si, tetramethylammonium hydroxide (TMAH), ammonium hydroxide (NH₄OH), or the like may be used to remove the first nanostructures 52.

In FIGS. 21A and 21B, gate dielectric layers 100 and gate electrodes 102 are formed for replacement gates. The gate dielectric layers 100 are deposited conformally in the second recesses 98. In the n-type region 50N and the p-type region 50P, the gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectric layers 100 may comprise an interfacial, silicon oxide layer and a metal oxide layer over the silicon oxide layer. In some embodiments, the gate dielectric layers 100 include a high-k dielectric material, and in these embodiments, the gate dielectric layers 100 may have a k value greater than 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 includes protection layers, such as silicon, barrier layers, such as titanium nitride, work function materials such as a metal-containing material such as titanium nitride, titanium oxide, tantalum nitride, tantalum carbide, cobalt, ruthenium, aluminum, titanium aluminum, tungsten, combinations thereof, or multi-layers thereof. For example, although single layer gate electrodes 102 are illustrated in FIGS. 19A and 19B, the gate electrodes 102 may comprise any number of liner layers, any number of work function tuning layers, and a fill material. Any combination of the layers which make up the gate electrodes 102 may be deposited in the n-type region 50N and the p-type region 50P between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

In FIGS. 22A-22C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. The gate mask 104 is optional and is omitted in some embodiments. Subsequently formed gate contacts (such as the contacts 114, discussed below with respect to FIGS. 24A-24C) penetrate through the gate mask 104 to contact the top surface of the recessed gate electrodes 102.

As further illustrated by FIGS. 22A-22C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 23A-23C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 23B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between 2 nm and 10 nm.

Next, in FIGS. 24A-24C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

In some embodiments, the contacts 112 in the p-type region 50P extend through the fourth semiconductor material layer 92D into the third semiconductor material layer 92C. In some embodiments, the contacts 112 in the p-type region 50P do not extend through the fourth semiconductor material layer 92D into the third semiconductor material layer 92C. In some other embodiments, only the silicide region 110 in the p-type region 50P extends through the fourth semiconductor material layer 92D into the third semiconductor material layer 92C.

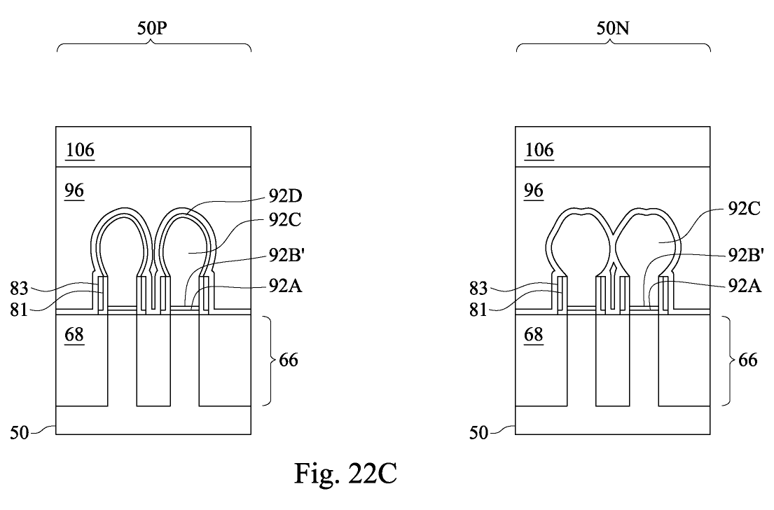

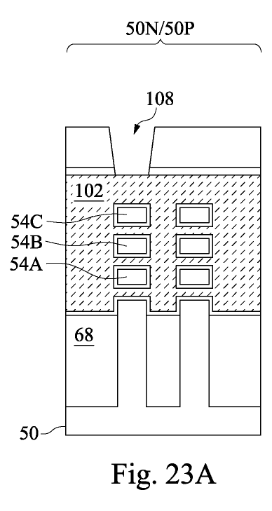

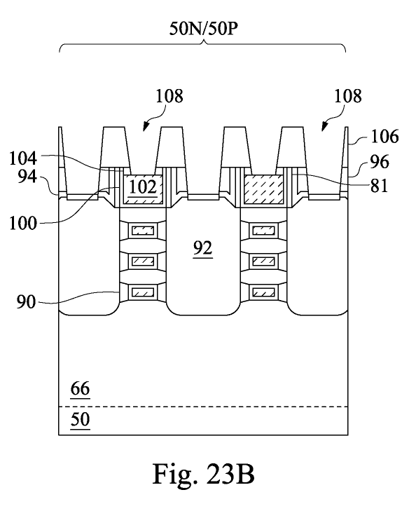

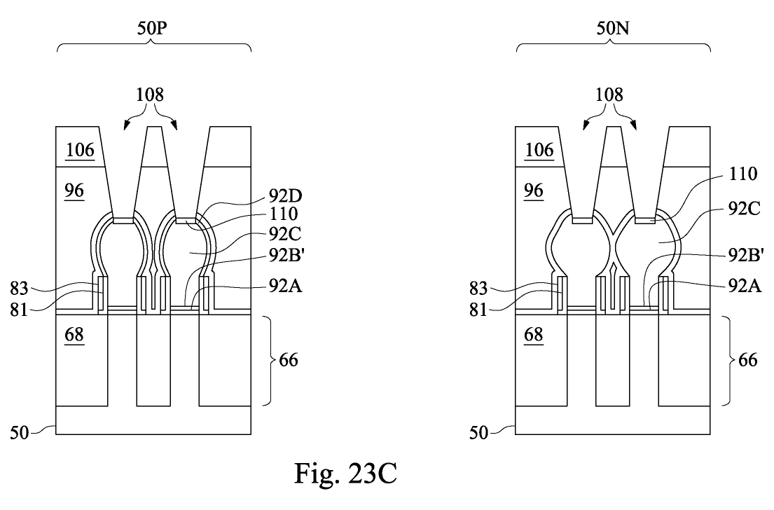

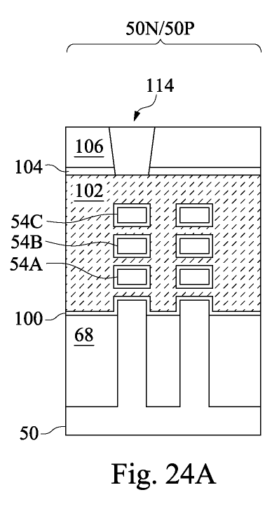

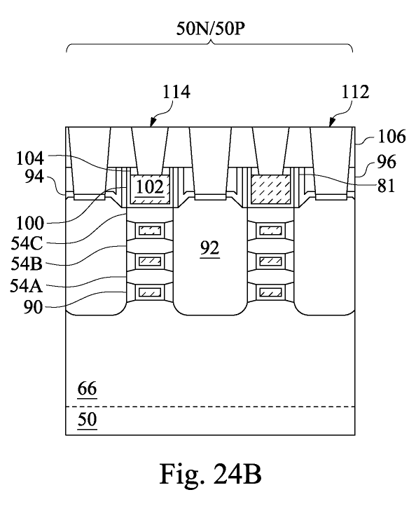

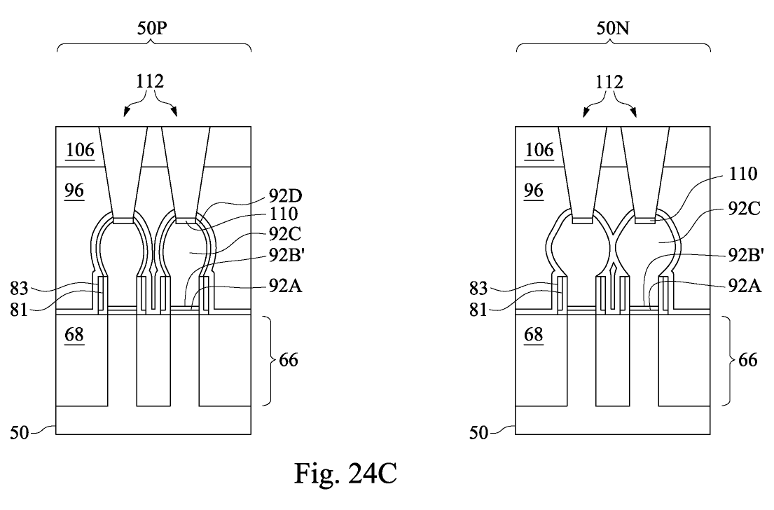

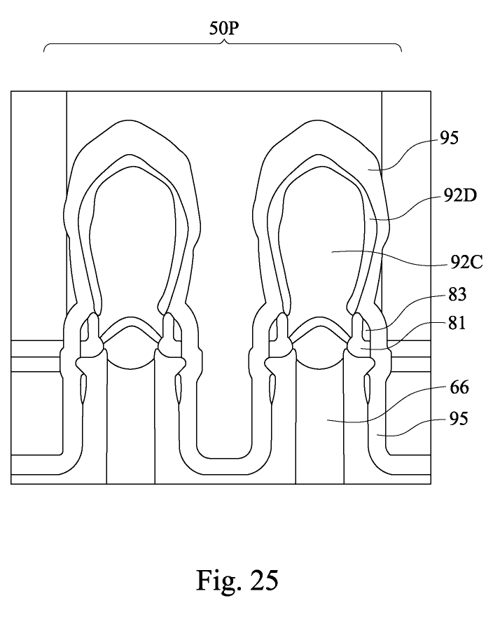

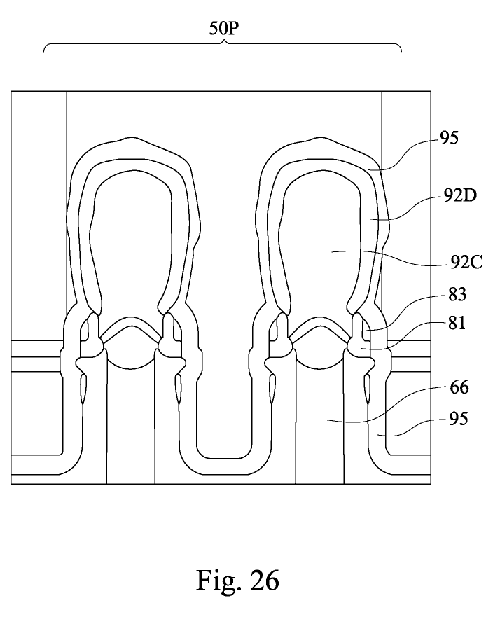

FIGS. 25 and 26 illustrate cross-sectional views of devices according to some embodiments. FIGS. 25 and 26 illustrate reference cross-section C-C’ illustrated in FIG. 1. In FIGS. 25 and 26, like reference numerals indicate like elements formed by like processes as the embodiment of FIGS. 2-24C. FIGS. 25 and 26 each illustrate the p-type region 50P at a similar point of processing as FIG. 15A.

FIGS. 25 and 26 illustrate the fourth semiconductor material layer 92D with different shapes in the cross-sectional view. These differences in shapes may be controlled by the shape of the underlying layer (e.g., 92C), the parameters of the formation process of layer 92D, and/or by crystallographic directions of the layers. For example, in FIG. 25, the fourth semiconductor material layer 92D has a more rounded or circular shape in the cross-sectional view. While the fourth semiconductor material layer 92D in FIG. 26 has a more squared-off shape or could be described as having a flat top in the cross-sectional view. In the embodiment of FIG. 25, the shape of fourth semiconductor material layer 92D is facet limited at the 111 plane which can be caused by an epitaxial growth temperature in a range from 600° to 700°C. In the embodiment of FIG. 26, the shape of fourth semiconductor material layer 92D is more conformal which can be caused by a lower epitaxial growth temperature in a range from 500° to 580°C.

Embodiments of the present disclosure may achieve advantages. By utilizing a high boron-doped silicon layer to protect the p-type source/drain regions in nano-FETs, the nano-FETs manufactured by the disclosed process have increased reliability and higher performance. In some configurations of nano-FET fabrication, the sequence of source/drain epitaxial processes involves forming n-type epitaxial regions after p-type epitaxial regions. The p-type epitaxial regions are protected by a protection layer (e.g., an aluminum oxide layer) during the n-type epitaxial process. However, the protection layer may not always provide uniform or sufficient coverage. Consequently, the underlying epitaxial layers of the p-type epitaxial structure can be damaged by etching chemicals, particularly chlorine-containing etchants used in subsequent n-type source/drain formation steps.

This disclosure addresses this issue by introducing a high boron-doped silicon layer as a part of the p-type source/drain epitaxial structure. This layer fully covers the underlying layer(s) and serves as a protective barrier. The high boron-doped silicon layer is particularly effective in safeguarding against HCl and Cl₂ etchants, providing a layer of protection when the protection layer proves insufficient. This significantly enhances the protection of p-type source/drain regions, ensuring their integrity throughout the fabrication process. This improved protection translates to increased reliability and higher performance of the resulting nano-FETs.

In an embodiment, a method may include forming a multi-layer stack over a substrate, the multi-layer stack having alternating layers of first semiconductor layers and second semiconductor layers. The method may also include forming first source/drain regions adjacent the first semiconductor layers and the second semiconductor layers in a first region, the first source/drain regions having a cap layer, forming a protection layer over the first source/drain regions, forming second source/drain regions adjacent the first semiconductor layers and the second semiconductor layers in a second region, removing the protection layer from over the first source/drain regions, replacing the first semiconductor layers in the first region with a first metal gate structure, and replacing the first semiconductor layers in the second region with a second metal gate structure.

The described embodiments may also include one or more of the following features. The method where the protection layer may include aluminum oxide. The method where first source/drain regions are part of a PMOS transistor. The method where the second source/drain regions are part of an NMOS transistor. The method where forming the protection layer over the first source/drain regions may include forming the protection layer over the first source/drain regions and the second source/drain regions, and removing the protection layer from over second source/drain regions. The method where forming the second source/drain regions adjacent the first semiconductor layers and the second semiconductor layers in the second region may include etching the second source/drain regions with a chlorine-containing etchant, the protection layer being exposed to the chlorine-containing etchant. The method where the cap layer of the first source/drain regions is exposed to the chlorine-containing etchant. The method where each of the first source/drain regions may include a first layer, a second layer over the first layer, and the cap layer over the second layer, the first layer being a silicon layer, the second layer being a boron doped silicon germanium layer, and the cap layer being a boron doped silicon layer. The method where the cap layer has a higher dopant concentration of boron than the second layer. The method where the cap layer may include germanium and has a lower concentration of germanium than the second layer. The method may include forming an interlayer dielectric over the first and second source/drain regions, and forming a conductive contact in the interlayer dielectric and electrically coupled to the first source/drain regions, the conductive contact extending through the cap layer of the first source/drain regions.

In an embodiment, a method may include forming a multi-layer stack over a substrate, the multi-layer stack having alternating layers of first semiconductor layers and second semiconductor layers. The method may also include forming first source/drain regions adjacent the first semiconductor layers and the second semiconductor layers in a first region, the first source/drain regions having a cap layer, forming a protection layer over the first source/drain regions, forming second source/drain regions adjacent the first semiconductor layers and the second semiconductor layers in a second region, etching the second source/drain regions with a chlorine-containing etchant, where the protection layer and the cap layer of the first source/drain regions are exposed to the chlorine-containing etchant, removing the protection layer from over the first source/drain regions, replacing the first semiconductor layers in the first region with a first metal gate structure, and replacing the first semiconductor layers in the second region with a second metal gate structure.

The described embodiments may also include one or more of the following features. The method where the protection layer may include aluminum oxide. The method where forming the first source/drain regions may include growing a first layer having silicon, growing a second layer over the first layer, the second layer having boron doped silicon germanium, and growing the cap layer over the second layer, the cap layer having boron doped silicon. The method where the cap layer has a higher dopant concentration of boron than the second layer, the cap layer may include germanium and has a lower concentration of germanium than the second layer, and the cap layer has a thickness in a range of 2 nm to 6 nm. The method where the cap layer may include Si, SiB, SiGe, or SiGeB.

In an embodiment, a semiconductor device may include a stack of channel regions over a substrate. The semiconductor device may also include first source/drain regions adjacent the stack of channel regions in a first region of the substrate, each of the first source/drain regions having, a first layer including silicon, a second layer over the first layer, the second layer including boron doped silicon germanium, a cap layer over the second layer, the cap layer having boron doped silicon, a first metal gate structure surrounding the channel regions in the first region, and conductive contacts over and electrically coupled to the first source/drain regions, the conductive contacts extending through the cap layer of the first source/drain regions.

The described embodiments may also include one or more of the following features. The semiconductor device where the cap layer has a higher dopant concentration of boron than the second layer, and the cap layer may include germanium and has a lower concentration of germanium than the second layer. The semiconductor device where the cap layer may include Si, SiB, SiGe, or SiGeB. The semiconductor device may include second source/drain regions adjacent the channel regions in a second region of the substrate, and a second metal gate structure surround the channel regions in the second region, where the first source/drain regions are part of a PMOS transistor and the second source/drain regions are part of an NMOS transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multi-layer stack over a substrate, the multi-layer stack comprising alternating layers of first semiconductor layers and second semiconductor layers;
forming first source/drain regions adjacent the first semiconductor layers and the second semiconductor layers in a first region, wherein forming the first source/drain regions comprises forming a first layer comprising undoped or lightly doped silicon that is substantially free of germanium, and forming a cap layer over the first layer, the cap layer covering an underlying layer of the first source/drain regions; and
forming second source/drain regions adjacent the first semiconductor layers and the second semiconductor layers in a second region, wherein forming the second source/drain regions comprises etching with a chlorine-containing etchant, the cap layer being exposed to the chlorine-containing etchant such that the cap layer shields the underlying layer of the first source/drain regions from the chlorine-containing etchant.

2. The method of claim 1, wherein forming the second source/drain regions further comprises, before the etching, forming a protection layer over the first source/drain regions, the protection layer comprising aluminum oxide.

3. The method of claim 1, wherein the chlorine-containing etchant comprises HCl or Cl₂.

4. The method of claim 1, wherein the first source/drain regions are part of a PMOS transistor, and the second source/drain regions are part of an NMOS transistor.

5. The method of claim 1, wherein forming the first source/drain regions further comprises forming a second layer comprising boron doped silicon germanium over the first layer before forming the cap layer, and wherein the cap layer comprises boron doped silicon having a lower germanium concentration than the second layer.

6. The method of claim 5, wherein the cap layer has a higher boron concentration than the second layer.

7. The method of claim 1, wherein the cap layer fully covers the underlying layer and maintains a thickness of the cap layer along (001), (110), and (111) crystallographic directions.

8. The method of claim 1, wherein the first layer reduces diffusion of dopants from overlying layers into the substrate.

9. A method comprising:
forming a multi-layer stack over a substrate, the multi-layer stack comprising alternating layers of first semiconductor layers and second semiconductor layers;
forming source/drain regions adjacent the first semiconductor layers and the second semiconductor layers, wherein forming the source/drain regions comprises:
growing a first layer comprising undoped or lightly doped silicon that is substantially free of germanium;
growing a semiconductor layer over the first layer; and
growing a cap layer over the semiconductor layer by an epitaxial growth process at a temperature in a range from 600°C to 700°C, the cap layer being facet limited at a (111) plane and having a rounded cross-sectional shape; and
replacing the first semiconductor layers with a metal gate structure.

10. The method of claim 9, wherein the semiconductor layer comprises boron doped silicon germanium, and the cap layer comprises boron doped silicon having a lower germanium concentration than the semiconductor layer.

11. The method of claim 10, wherein the cap layer has a higher boron concentration than the semiconductor layer.

12. The method of claim 9, wherein the cap layer comprises Si, SiB, SiGe, or SiGeB.

13. The method of claim 9, wherein the source/drain regions are first source/drain regions in a first region, the method further comprising forming second source/drain regions in a second region, wherein forming the second source/drain regions comprises etching with a chlorine-containing etchant to which the cap layer is exposed, the cap layer shielding the first source/drain regions from the chlorine-containing etchant.

14. The method of claim 9, wherein the first layer reduces diffusion of dopants from overlying layers into the substrate.

15. The method of claim 9, further comprising forming a conductive contact electrically coupled to the source/drain regions and extending through the cap layer.

16. A semiconductor device comprising:
a stack of channel regions;
first source/drain regions adjacent the stack of channel regions, each of the first source/drain regions comprising:
a first layer comprising undoped or lightly doped silicon that is substantially free of germanium;
a second layer over the first layer, the second layer comprising boron doped silicon germanium; and
a cap layer over the second layer, the cap layer comprising boron doped silicon, the cap layer having a higher boron concentration than the second layer and a lower germanium concentration than the second layer;
a metal gate structure surrounding the channel regions; and
conductive contacts over and electrically coupled to the first source/drain regions, the conductive contacts extending through the cap layer of the first source/drain regions into the second layer.

17. The semiconductor device of claim 16, further comprising a substrate and a fin protruding from the substrate, wherein the stack of channel regions is over the fin, and wherein the first layer reduces diffusion of dopants from the second layer into the substrate.

18. The semiconductor device of claim 16, wherein the cap layer fully covers the second layer and maintains a thickness of the cap layer along (001), (110), and (111) crystallographic directions.

19. The semiconductor device of claim 16, further comprising second source/drain regions adjacent the stack of channel regions, the second source/drain regions omitting the cap layer, wherein the first source/drain regions are part of a PMOS transistor and the second source/drain regions are part of an NMOS transistor.

20. The semiconductor device of claim 16, wherein the cap layer comprises Si, SiB, SiGe, or SiGeB.
